(19) United States
(12) Patent Application Publication
(10) Pub. No.: US 2012/0129315 A1
(43) Pub. Date: May 24, 2012

(54) Method for fabricating semiconductor package

(75) Inventors: Yeh-Chang Hu, Taichung (TW); Chung-Tang Lin, Taichung (TW); Hui-Min Huang, Taichung (TW); Yih-Jenn Jiang, Taichung (TW); Shih-Kuang Chiu, Taichung (TW)

(73) Assignee: SILICONWARE PRECISION INDUSTRIES CO., LTD., Taichung Hsien (TW)

(21) Appl. No.: 12/930,659

(22) Filed: Jan. 12, 2011

(30) Foreign Application Priority Data
Nov. 18, 2010 (TW) 099139658

(51) Int. Cl. H01L 21/50

(52) U.S. Cl. 438/401; 257/E21.499

(57) ABSTRACT

A method for fabricating a semiconductor package includes the steps of: providing an alignment board having a plurality of openings and a plurality of alignment marks corresponding to the openings, respectively; disposing a plurality of chips on the alignment board at positions corresponding to the openings according to the alignment marks; pressing the alignment board with a carrier board having a soft layer disposed on one surface thereof so as to embed the chips in the soft layer of the carrier board; and removing the alignment board. As such, the positions of the chips are accurately positioned according to the alignment marks on the alignment board.

### BACKGROUND OF THE INVENTION

1. Field of the Invention

The present invention relates to methods for fabricating semiconductor packages, and more particularly, to a method for fabricating a semiconductor package with embedded chips.

2. Description of Related Art

Along with the rapid development of electronic industries, electronic products are developed towards multi-function and high performance. Currently, there are different types of package substrates for carrying semiconductor chips, such as wire-bonding package substrates, chip scale package (CSP) substrates, flip-chip ball grid array (FCBGA) substrates and so on. For example, a chip can be disposed on a package substrate and electrically connected to the package substrate through conductive bumps or gold wires.

Further, chip-embedded packages are developed to meet the requirement of high multi-function, high operating efficiency, high integration and miniaturization. FIGS. 1A to 1C disclose a conventional fabrication method of a wafer level chip scale package (WLCSP) disclosed by US patent application No. 2008/0012144 and U.S. Pat No. 7,189,596.

Referring to FIGS. 1A and 1A′, alignment mark K are disposed on the four corners of a carrier board 10 and an adhesive film 11 is formed on the carrier board 10. According to the alignment marks K, a plurality of chips 12 each having an active surface with a plurality of electrode pads 120 are provided and array arranged on the adhesive film 11 of the carrier board 10 via the active surface thereof. Referring to FIG. 1B, a packaging material 14 is formed on the adhesive film 11 and the chips 12. Referring to FIG. 1C, the carrier board 10 and the adhesive film 11 are removed to expose the electrode pads 120.

However, in the above-described process, since the chip is attached to the adhesive film via the active surface thereof, if the adhesive film 11 expands under heat, displacement of the chip 12 may occur. Therefore, a subsequent RDL (redistribution layer) process is adversely affected such that wiring circuits formed in the RDL process cannot be effectively electrically connected to the electrode pads 120, thereby reducing the product yield.

Therefore, how to overcome the above-described drawback has become urgent.

### SUMMARY OF THE INVENTION

Accordingly, the present invention provides a method for fabricating a semiconductor package, which comprises the steps of: providing an alignment board having a plurality of openings and a plurality of alignment marks corresponding to the openings, respectively; disposing a plurality of chips on the alignment board at positions corresponding to the openings according to the alignment marks; pressing the alignment board with a carrier board having a soft layer disposed on one surface thereof so as to embed the chips in the soft layer of the carrier board; and removing the alignment board.

Therein, the carrier board can be made of silicon or copper, and the soft layer can be made of a molding compound, a dry film or an ABF (ajinomoto build-up film).

Therein, the alignment marks can be disposed at the edges of the openings.

Therein, a release film can be interposed between the carrier board and the soft layer such that the carrier board can be easily removed via the release film.

In the above-described method, the chips can be disposed on the alignment board via an adhesive material. The adhesive material can be pre-formed at the edges of the openings of the alignment board, and removed along with the alignment board. Further, the adhesive material can be dissolved by a solvent and thus removed.

Therein, after the step of embedding the chips in the soft layer and before the step of removing the alignment board, the method can further comprise the step of curing the soft layer.

Since the method of the present invention disposes a plurality of chips on an alignment board instead of a conventional adhesive film, displacement of the chips caused by expansion of the adhesive film under heat as in the prior art is prevented. Further, by embedding the chips in a soft layer, the present invention avoids possible displacement of the chips owning to a dot-shaped adhesive material disposed between the chip and the alignment board, thereby facilitating a subsequent RDL process such that wiring circuits formed in the RDL process can be effectively electrically connected to the chips. As such, the product yield is improved.

Further, the chips can be accurately positioned according to the alignment marks of the alignment board.

### BRIEF DESCRIPTION OF DRAWINGS

FIGS. 1A to 1C are cross-sectional views showing a conventional method for fabricating a semiconductor package, wherein FIG. 1A′ is an upper view of FIG. 1A; and

FIGS. 2A to 2E are cross-sectional views showing a method for fabricating a semiconductor package according to the present invention, wherein FIG. 2A′ is an upper view of FIG. 2A, and FIGS. 2D′ and 2E′ show another embodiment of FIGS. 2D and 2E.

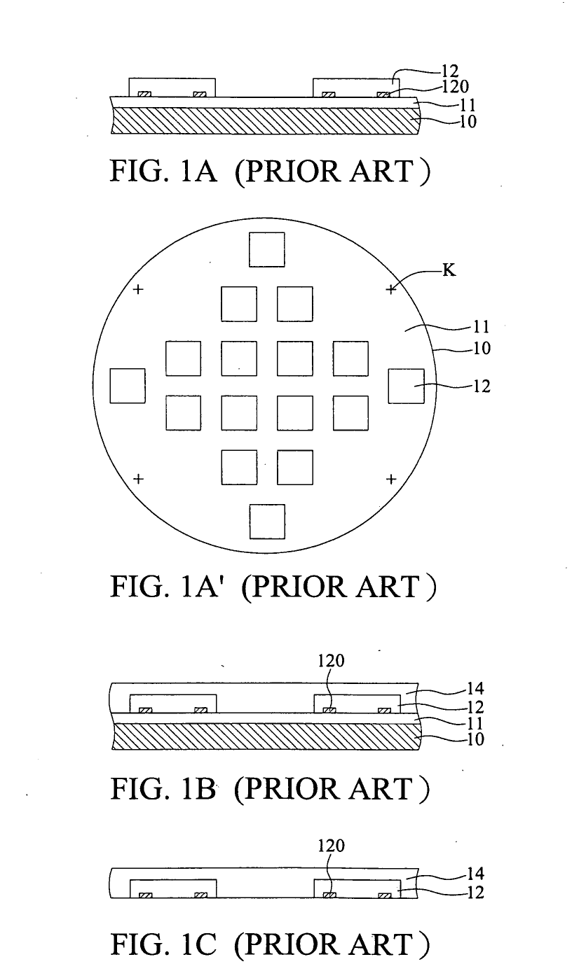

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “one”, “above”, etc. are merely for illustrative purpose and should not be construed to limit the scope of the present invention.

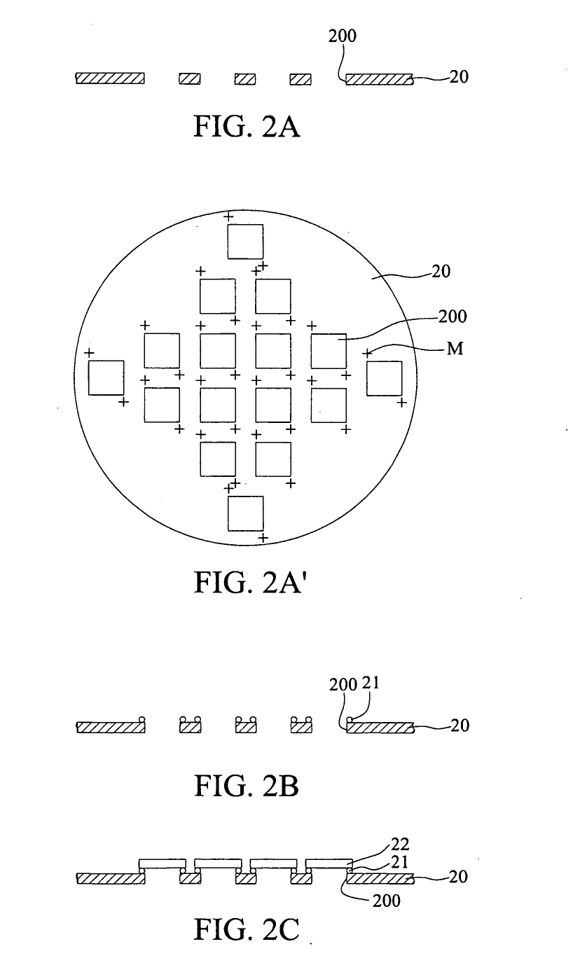

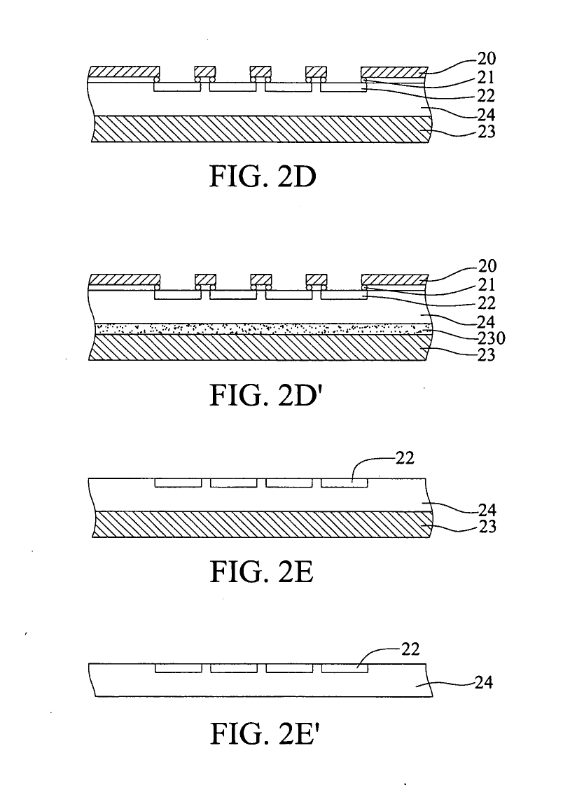

FIGS. 2A to 2E show a method for fabricating a semiconductor package according to the present invention.

Referring to FIGS. 2A and 2A′, an alignment board 20 having a plurality of openings 200 is provided, and a plurality of alignment marks M is provided at the edges of the openings 200a, respectively. For example, the alignment marks M can be diagonally arranged at each of the openings 200.

Referring to FIG. 2B, an adhesive material 21 of a dot shape is formed on the alignment board 20 at the edges of the openings 200, but the shape of the adhesive material is not limited thereto.

Referring to FIG. 2C, according to the alignment marks M, a plurality of chips 22 are disposed on the alignment board 20 at positions corresponding to the openings 200 via the adhesive material 21.

Referring to FIG. 2D, the alignment board 20 is pressed with a carrier board 23 having a soft layer 24 disposed on one surface thereof so as to completely embed the chip 22 in the soft layer 24. Then, the soft layer 24 is cured to secure the chip 22 in the soft layer 24.

In the present embodiment, the carrier board 23 can be made of various materials according to the package requirement. For example, the carrier board 23 can be made of silicon. Alternatively, the carrier board 23 can be made of copper to function as a heat sink. The soft layer 24 can be made of a dielectric material such as a molding compound, a dry film or an ABF (ajinomoto build-up film).

Referring to FIG. 2E, the adhesive material 21 is dissolved by a solvent such that the adhesive material 21 and the alignment board 20 are removed to expose the chips 22. In the present embodiment, the alignment board 20 can be immersed in an acetone solution so as to cause the acetone solution to flow between the alignment board 20 and the carrier board 23 to dissolve the adhesive material 21. Further, the dissolving process can be accelerated by ultrasonic vibration.

Subsequently, an RDL (redistribution layer) process can be performed. If the carrier board 23 is a silicon wafer, it provides a supporting function so as to avoid warpage of the structure. If the carrier board 23 is a copper board, it provides not only a supporting function but also a heat dissipating function.

Since the chips 22 are disposed on the alignment board 20 instead of a conventional adhesive film, the present invention prevents displacement of the chips 22 caused by expansion of the adhesive film under heat as in the prior art. Further, by embedding the chips 22 in the soft layer 24, the present invention avoids possible displacement of the chips 22 owning to the adhesive material 21. Since no displacement of the chips occurs, the subsequent RDL process can be smoothly performed such that wiring circuits formed in the RDL process can be effectively electrically connected to the chip 22, thereby improving the product yield.

Furthermore, the chips 22 can be accurately positioned in terms of the alignment marks M and the openings 200 of the alignment board 20.

In another embodiment, as shown in FIG. 2D′, a release film 230 is interposed between the carrier board 23 and the soft layer 24. Subsequently, as shown in FIG. 2E′, the alignment board 20 and the adhesive material 21 are first removed and then the carrier board 23 is removed via the release film 230.

Therefore, the method of the present invention involves disposing a plurality of chips on an alignment board and embedding the chips in a soft layer so as to prevent displacement of the chips, thereby facilitating a subsequent RDL process and improving the product yield.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

1. A method for fabricating a semiconductor package, comprising the steps of:
providing an alignment board having a plurality of openings and a plurality of alignment marks corresponding to the openings, respectively;
disposing a plurality of chips on the alignment board at positions corresponding to the openings according to the alignment marks, wherein each of the chips is disposed correspondingly above each of the openings;
pressing the alignment board with a carrier board having a soft layer disposed on one surface thereof so as to embed the chips in the soft layer of the carrier board; and
removing the alignment board.

2. The method of claim 1, wherein the carrier board is made of one of silicon and copper.

3. The method of claim 1, wherein the alignment marks are disposed at edges of the openings.

4. The method of claim 1, wherein the soft layer is made of one of a molding compound, a dry film and build-up film.

5. The method of claim 1, wherein a release film is further interposed between the carrier board and the soft layer.

6. The method of claim 5, wherein after the step of removing the alignment board, the method further comprises the step of removing the carrier board via the release film.

7. The method of claim 1, wherein the chips are disposed on the alignment board via an adhesive material.

8. The method of claim 7, wherein the adhesive material is pre-formed at edges of the openings of the alignment board.

9. The method of claim 7, wherein the adhesive material is removed along with the alignment board.

10. The method of claim 9, wherein the adhesive material is removed by a solvent.

11. The method of claim 1, wherein after the step of embedding the chips in the soft layer and before the step of removing the alignment board, the method further comprises the step of curing the soft layer.
